(19) United States
(12) Patent Application Publication
(10) Pub. No.: US 2024/0147768 A1
(43) Pub. Date: May 2, 2024

(54) PIXEL AND DISPLAY DEVICE COMPRISING THE SAME

(71) Applicant: Samsung Display Co., LTD., Yongin-si (KR)

(72) Inventors: Ji Hye HAN, Yongin-si (KR); Hyun Eok SHIN, Yongin-si (KR); Chul Min BAE, Yongin-si (KR)

(73) Assignee: Samsung Display Co., LTD., Yongin-si (KR)

(21) Appl. No.: 18/334,452

(22) Filed: Jun. 14, 2023

(30) Foreign Application Priority Data
Oct. 31, 2022 (KR) 10-2022-0142884

(51) Int. Cl. H10K 59/122; H10K 59/38; H10K 59/80

(52) U.S. Cl. CPC H10K 59/122; H10K 59/38; H10K 59/873; H10K 59/878; H10K 59/879; H10K 59/8792

(57) ABSTRACT

A pixel includes: a via layer disposed on a substrate; a first electrode disposed on the via layer; a pixel defining layer disposed on the first electrode, the pixel defining layer including an opening exposing a portion of the first electrode; an emission layer disposed on the portion of the first electrode and the pixel defining layer; and a second electrode disposed on the emission layer. The first electrode includes a first layer disposed on the via layer and a second layer disposed between the first layer and the pixel defining layer. The first layer includes a plurality of sub-insulating layers, each of the plurality of sub-insulating layers including a first sub-layer and a second sub-layer that are sequentially stacked. The first sub-layer and the second sub-layer have different refractive indices.

### CROSS-REFERENCE TO RELATED APPLICATION(S)

This application claims priority to and benefits of Korean patent application No. 10-2022-0142884 under 35 U.S.C. § 119, filed on Oct. 31, 2022, in the Korean Intellectual Property Office, the entire contents of which are incorporated herein by reference.

### BACKGROUND

### 1. Technical Field

Embodiments relate to a pixel and a display device including the pixel.

### 2. Description of the Related Art

Recently, as interest in information displays is increased, research and development of display devices have been continuously conducted.

### SUMMARY

Embodiments provide a pixel having improved reliability.

Embodiments also provide a display device including the pixel.

However, embodiments of the disclosure are not limited to those set forth herein. The above and other embodiments will become more apparent to one of ordinary skill in the art to which the disclosure pertains by referencing the detailed description of the disclosure given below.

In accordance with an aspect of the disclosure, a pixel may include: a via layer disposed on a substrate; a first electrode disposed on the via layer; a pixel defining layer disposed on the first electrode, the pixel defining layer including an opening exposing a portion of the first electrode; an emission layer disposed on the portion of the first electrode and the pixel defining layer; and a second electrode disposed on the emission layer. The first electrode may include a first layer disposed on the via layer and a second layer disposed between the first layer and the pixel defining layer. The first layer may include a plurality of sub-insulating layers, each of the plurality of sub-insulating layers including a first sub-layer and a second sub-layer that are sequentially stacked. The first sub-layer and the second sub-layer may have different refractive indices.

The first layer may include a Bragg reflection layer to reflect light toward the second layer, the light that is emitted from the emission layer and transmitted toward the via layer.

The first sub-layer may include a first inorganic layer having a first refractive index, and the second sub-layer may include a second inorganic layer having a second refractive index.

The first refractive index may be smaller than the second refractive index. The first inorganic layer may include SiOCF:H, and the second inorganic layer may include Nb₂O₅.

The second layer may include a transparent conductive material.

The second layer may include at least one of indium tin oxide and tungsten oxide.

The pixel may further include at least one transistor disposed between the substrate and the via layer. The via layer may include a via hole exposing a portion of the at least one transistor. The second layer may be electrically connected to the at least one transistor through the via hole.

The first layer may not be disposed in the via hole.

The pixel may further include a thin film encapsulation layer disposed on the second electrode. The thin film encapsulation layer may include a first encapsulation layer disposed on the second electrode, a second encapsulation layer disposed on the first encapsulation layer, and a third encapsulation layer disposed on the second encapsulation layer. The first and third encapsulation layers may include an inorganic layer, and the second encapsulation layer may include an organic layer.

The pixel may further include: a color conversion layer disposed on the thin film encapsulation layer; and a color filter layer disposed on the color conversion layer.

The color conversion layer may include: a bank disposed on an upper surface of the thin film encapsulation layer and overlapping the pixel defining layer; and a color conversion pattern layer disposed on the upper surface of thin film encapsulation layer. The color conversion pattern layer may be surrounded by the bank. The color conversion pattern layer may convert light emitted from the emission layer into light of a specific color.

The color filter layer may include: a color filter disposed on the color conversion pattern layer; and a light blocking pattern layer disposed adjacent to the color filter. The light blocking pattern layer may be disposed in a non-emission area.

The light blocking pattern layer may include a black matrix.

The pixel may further include an intermediate layer disposed between the thin film encapsulation layer and the color conversion layer. The intermediate layer may include an adhesive material.

The pixel may further include: a first capping layer disposed between the color conversion layer and the color filter layer; a second capping layer disposed between the intermediate layer and the color conversion layer; and a base layer disposed on an upper surface of the color filter layer.

The pixel may further include an anti-reflection layer disposed on the base layer.

The emission layer may be configured to emit blue-based light.

In accordance with another aspect of the disclosure, a display device may include: a substrate including an emission area and a non-emission area; a via layer disposed on the substrate; a (1-1)th electrode, a (1-2)th electrode, and a (1-3)th electrode disposed on the via layer in the emission area, the (1-1)th electrode, the (1-2)th electrode, and the (1-3)th electrode being spaced apart from each other; a pixel defining layer disposed on the (1-1)th electrode, the (1-2)th electrode, the (1-3)th electrode, and the via layer, the pixel defining layer including an opening exposing a portion of each of the (1-1)th electrode, the (1-2)th electrode, and the (1-3)th electrode in the emission area: an emission layer disposed on the pixel defining layer; and a second electrode disposed on the emission layer. Each of the (1-1)th electrode, the (1-2)th electrode, and the (1-3)th electrode includes a first layer disposed on the via layer and a second layer disposed between the first layer and the pixel defining layer. The first layer includes a plurality of sub-insulating layers, each of the plurality of sub-insulating layers including a first sub-layer and a second sub-layer, which are sequentially stacked with each other. The first sub-layer and the second sub-layer have different refractive indices.

The first layer may include a Bragg reflection layer to reflect light toward the second layer, the light that is emitted from the emission layer and transmitted toward the via layer. The first sub-layer may include a first inorganic layer having a first refractive index, and the second sub-layer may include a second inorganic layer having a second refractive index.

The first refractive index may be smaller than the second refractive index. The first inorganic layer may include SiOCF:H, and the second inorganic layer may include Nb₂O₅.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it may be the only element between the two elements, or one or more intervening elements may also be present. Like reference numerals refer to like elements throughout.

FIG. 1 is a schematic plan view schematically illustrating a display device in accordance with an embodiment.

FIG. 2 is a schematic block diagram illustrating an embodiment of pixels and a driver in a display device in accordance with an embodiment.

FIG. 3 is a schematic cross-sectional view illustrating a display device in accordance with an embodiment.

FIG. 4 is a circuit diagram schematically illustrating an electrical connection relationship of components included in each of pixels shown in FIG. 2.

FIG. 5 is a schematic plan view illustrating a pixel in accordance with an embodiment.

FIG. 6 is a schematic cross-sectional view taken along line I-I′ shown in FIG. 5.

FIGS. 7 and 8 are schematic cross-sectional views taken along line II-II′ shown in FIG. 5.

FIGS. 9 and 10 are schematic enlarged views illustrating portion EA1 shown in FIG. 6.

FIG. 11 is a schematic enlarged view illustrating portion EA2 shown in FIG. 6.

FIGS. 12 and 13 illustrate a pixel in accordance with an embodiment, and are schematic cross-sectional views taken along the line II-II′ shown in FIG. 5.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

The disclosure may apply various changes and different shape, therefore only illustrate in detail with examples. However, the examples do not limit to certain shapes but apply to all the change and equivalent material and replacement. The drawings included are illustrated a fashion where the figures are expanded for the better understanding.

Like numbers refer to like elements throughout. In the drawings, the thickness of certain lines, layers, components, elements or features may be exaggerated for clarity. It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

The terminology used herein is for the purpose of describing particular embodiments and is not intended to be limiting. As used herein, the singular forms, “a,” “an,” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

In this specification, it will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. In this specification, the term “connection” or “coupling” may inclusively mean connection or physical and/or electrical coupling.

Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

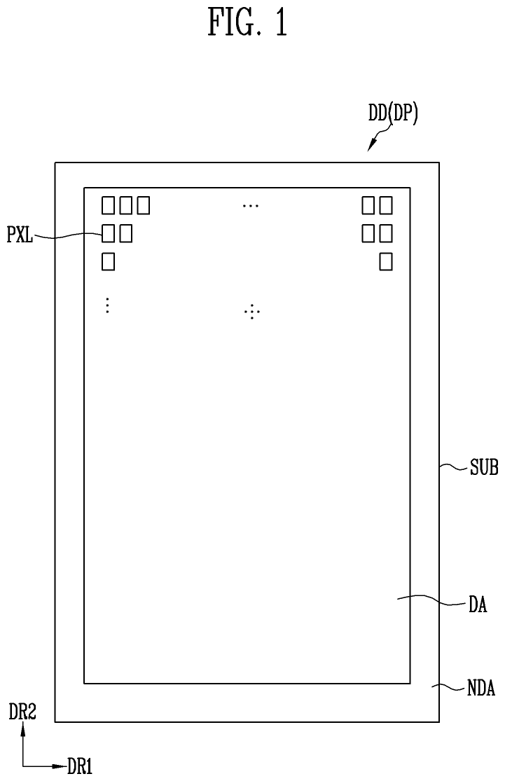

FIG. 1 is a plan view schematically illustrating a display device DD in accordance with an embodiment.

In FIG. 1, for convenience of description, a structure of the display device DD, the display panel DP provided in the display device DD is illustrated based on a display area DA in which an image is displayed.

Referring to FIG. 1, the display device in accordance with the embodiment may include a substrate SUB, pixels PXL disposed on the substrate SUB, a driver which is provided on the substrate SUB and drives the pixels PXL, and a line part connecting the pixels PXL and the driver to each other.

The substrate SUB may include a transparent insulating material capable of transmitting light therethrough. The substrate SUB may be a rigid substrate or a flexible substrate.

The rigid substrate may be, for example, one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

An area on the substrate SUB may be provided as the display area DA such that the pixels PXL are disposed therein, and the other area on the substrate SUB may be provided as a non-display area NDA. For example, the substrate SUB may include the display area DA including pixel areas in which the respective pixels PXL are disposed and the non-display area NDA disposed at the periphery of the display area DA (or adjacent to the display area DA).

The display area DA may have various shapes. For example, the display area DA may be provided in various shapes such as a closed polygonal including linear sides, a circle, an ellipse or the like, including a curved side, and a semicircle, a semi-ellipse or the like, including linear and curved sides.

The non-display area NDA may be provided at least one side of the display area DA. For example, the non-display area NDA may surround a circumference of the display area DA.

The pixels PXL may be provided in the display area DA of the substrate SUB, and be electrically connected to lines.

Each of the pixels PXL may include a light emitting element emitting white light and/or colored light and a pixel circuit for driving the light emitting element. The pixel circuit may include at least one transistor electrically connected to the light emitting element.

Each pixel PXL may emit light of any one color among red, green, and blue. However, embodiments are not limited thereto, and each pixel PXL may emit light of one color among cyan, magenta, yellow, and white.

The pixels PXL may be arranged in a matrix form along rows extending in a first direction DR1 and columns extending in a second direction DR2 intersecting the first direction DR1. However, the arrangement form of the pixels PXL is not limited, and the pixels PXL may be arranged in various forms.

The driver may provide a signal to each pixel PXL through the line part, and accordingly, driving of each pixel PXL may be controlled. The driver may supply a data signal corresponding to an image data signal to the pixels PXL by sequentially scanning the pixels PXL of the display area DA. The display device DD may display an image corresponding to image data.

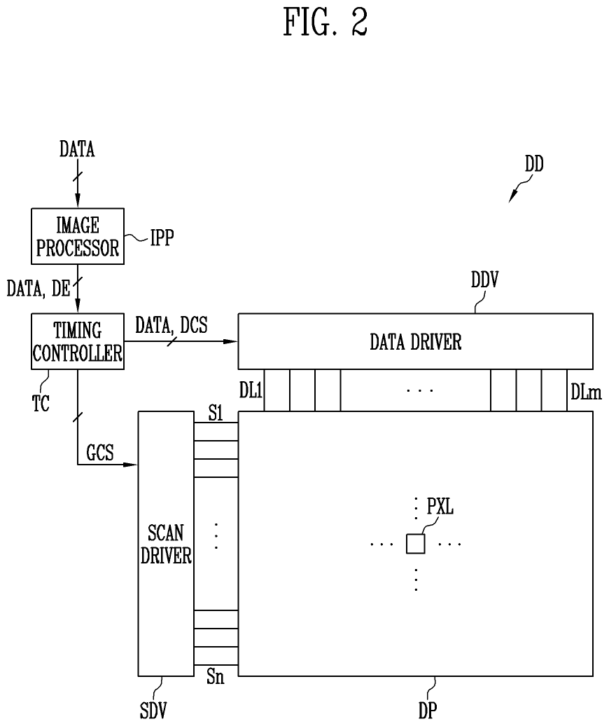

FIG. 2 is a schematic block diagram illustrating pixels PXL and a driver in a display device DD in accordance with an embodiment.

Referring to FIGS. 1 and 2, the display device in accordance with the embodiment may include a display panel DP, a driver, and a line part.

The display panel DP may display an image, corresponding to a data signal DATA and a scan signal, which are supplied from a data driver DDV and a scan driver SDV. The display panel DP may include pixels PXL for displaying the image.

The driver may include an image processor IPP, a timing controller TC, the data driver DDV, and the scan driver SDV.

The image processor IPP may output a data enable signal DE and the like together with a data signal DATA supplied from the outside. The image processor IPP may output at least one of a vertical synchronization signal, a horizontal synchronization signal, and a clock signal, in addition to the data enable signal DE.

The timing controller TC may receive the data enable signal DE or a driving signal including the vertical synchronization signal, the horizontal synchronization signal, the clock signal, and the like, and the data signal DATA, which are supplied from the image processor IPP. The timing controller TC may output a gate control signal GCS for controlling an operation timing of the scan driver SDV and a data control signal DCS for controlling an operation timing of the data driver DDV, based on the driving signal.

The data driver DDV may convert a data signal DATA supplied from the timing controller TC into a corresponding data voltage and output the data voltage in response to the data control signal DCS supplied from the timing controller TC. The data driver DDV may supply the data voltage to data lines DL1 to DLm. The data voltage supplied to the data lines DL1 to DLm may be supplied to pixels PXL selected by a scan signal.

The scan driver SDV may apply a scan signal to scan lines S1 to Sn in response to the gate control signal GCS supplied from the timing controller TC. For example, in case that the scan driver SDV sequentially supplies the scan signal to the scan lines S1 to Sn, the pixels PXL may be sequentially selected in units of horizontal lines.

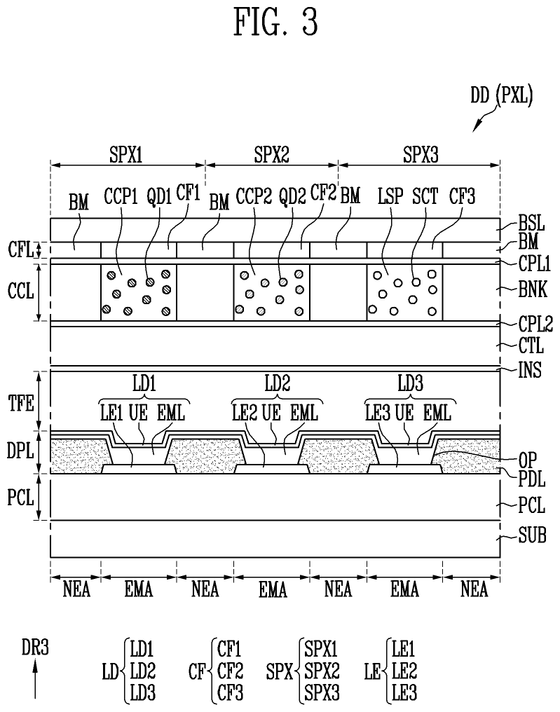

FIG. 3 is a schematic cross-sectional view illustrating a display device DD in accordance with an embodiment.

In FIG. 3, for convenience of description, a sectional structure (or stacked structure) of the display device DD is illustrated based on a pixel PXL formed on a substrate SUB, and a thickness direction of the substrate SUB is indicated as a third direction DR3.

Referring to FIGS. 1 to 3, the display device DD may include at least one pixel PXL disposed in the display area DA (see FIG. 1) of the substrate SUB. The pixel PXL may be provided in a pixel area of the display area DA. The pixel area may include an emission area EMA and a non-emission area NEA.

The pixel PXL may include at least one sub-pixel SPX. For example, the pixel PXL may include a first sub-pixel SPX1, a second sub-pixel SPX2, and a third sub-pixel SPX3.

In case that a first sub-pixel SPX1, a second sub-pixel SPX2, and a third sub-pixel SPX3 are inclusively designated, each of the first, second, and third sub-pixels SPX1, SPX2, and SPX3 and/or the first, second, and third sub-pixels SPX1, SPX2, and SPX3 will be referred to as a “sub-pixel SPX” and/or “sub-pixels SPX.”

Each of the first, second, and third sub-pixels SPX1, SPX2, and SPX3 may include the substrate SUB, a pixel circuit layer PCL, a display element layer DPL, and a thin film encapsulation layer TFE.

The pixel circuit layer PCL may include a pixel circuit provided on the substrate SUB and signal lines electrically connected to the pixel circuit. For example, the pixel circuit layer PCL may include at least one insulating layer positioned between components included in the pixel circuit.

The display element layer DPL may be positioned on the pixel circuit layer PCL. The display element layer DPL may include a light emitting element LD emitting light. The light emitting element LD may include a first electrode LE, an emission layer EML, and a second electrode UE. The first electrode LE may be an anode, and the second electrode UE may be a cathode. The second electrode UE may be a common layer commonly provided in adjacent sub-pixels SPX.

The first electrode LE may include a (1-1)th electrode LE1, a (1-2)th electrode LE2, and a (1-3)th electrode LE3. The (1-1)th electrode LE1 may be positioned in the first sub-pixel SPX1, the (1-2)th electrode LE2 may be positioned in the second sub-pixel SPX2, and the (1-3)th electrode LE3 may be positioned in the third sub-pixel SPX3.

A pixel defining layer PDL may be positioned over the first electrode LE. The pixel defining layer PDL may include an opening OP exposing each of a portion of the (1-1)th electrode LE1, a portion of the (1-2)th electrode LE2, and a portion of the (1-3)th electrode LE3. The pixel defining layer PDL may be a structure for defining (or partitioning) an emission area EMA of each of the first, second, and third sub-pixels SPX1, SPX2, and SPX3.

The emission layer EML may cover the (1-1)th electrode LE1 exposed by an opening OP of the pixel defining layer PDL, the (1-2)th electrode LE2 exposed by another opening OP of the pixel defining layer PDL, and the (1-3)th electrode LE3 exposed by still another opening OP of the pixel defining layer PDL. The emission layer EML may be a common layer commonly disposed in the first, second, and third sub-pixels SPX1, SPX2, and SPX3, but embodiments are not limited thereto. The emission layer EML may emit, for example, blue-based light. The emission layer EML may include a light generation layer emitting light, an electron transport layer, a hole transport layer, and the like.

The second electrode UE may be positioned on the emission layer EML, thereby covering the emission layer EML. The second electrode UE may be a transmissive electrode, and may include a transparent conductive material. The second electrode UE may be a common layer commonly provided in the first, second, and third sub-pixels SPX1, SPX2, and SPX3.

The (1-1)th electrode LE1, the emission layer EML on the (1-1)th electrode LE1, and the second electrode UE on the emission layer EML may form a first light emitting element LD1. The first light emitting element LD1 may be positioned in the first sub-pixel SPX1.

The (1-2)th electrode LE2, the emission layer EML on the (1-2)th electrode LE2, and the second electrode UE on the emission layer EML may form a second light emitting element LD2. The second light emitting element LD2 may be positioned in the second sub-pixel SPX2.

The (1-3)th electrode LE3, the emission layer EML on the (1-3)th electrode LE3, and the second electrode UE on the emission layer EML may form a third light emitting element LD3. The third light emitting element LD3 may be positioned in the third sub-pixel SPX3.

The thin film encapsulation layer TFE may be positioned on the second electrode UE.

The thin film encapsulation layer TFE may be formed as a single layer, but be formed as a multi-layer. The thin film encapsulation layer TFE may include insulating layers covering the first, second, and third light emitting elements LD1, LD2, and LD3. For example, the thin film encapsulation layer TFE may include at least one inorganic layer and at least one organic layer. For example, the thin film encapsulation layer TFE may have a structure in which an inorganic layer and an organic layer are alternately stacked with each other. In some embodiments, the thin film encapsulation layer may be an encapsulation substrate which is disposed over the first, second, and third light emitting elements LD1, LD2, and LD3 and is coupled (or bonded) to the substrate SUB through a sealant.

An intermediate layer CTL, a color conversion layer CCL, a color filter layer CFL, and a base layer BSL may be disposed on a top surface (or upper surface) of the thin film encapsulation layer TFE.

The intermediate layer CTL may be disposed on the thin film encapsulation layer TFE. For example, an insulating layer INS may be disposed between the intermediate layer CTL and the thin film encapsulation layer TFE.

The intermediate layer CTL may be a transparent adhesive layer (or cohesive layer), e.g., an optically clear adhesive for reinforcing adhesion between the thin film encapsulation layer TFE and the color conversion layer CCL, but embodiments are not limited thereto. In some embodiments, the intermediate layer CTL may be a refractive index conversion layer for converting a refractive index of light which is emitted from emission layer EML and may transmit toward the color conversion layer CCL, thereby improving the light emitting luminance of the pixel PXL. In some embodiments, the intermediate layer CTL may include a filler formed of an insulating material having insulative and adhesive properties.

The insulating layer INS may be an inorganic layer including an inorganic material. The insulating layer INS may include at least one of silicon nitride (SiNₓ), silicon oxide (SiOₓ), and silicon oxynitride (SiOₓN_{y}), or include at least one of metal oxides such as such as aluminum oxide (AlOₓ). However, embodiments are not limited thereto. The insulating layer INS may be formed as a single layer, but be formed as a multi-layer including at least two layers.

The color conversion layer CCL may be disposed on the intermediate layer CTL. For example, a second capping layer CPL2 may be disposed between the color conversion layer CCL and the intermediate layer CTL.

The color conversion layer CCL may include a bank BNK, first and second color conversion pattern layers CCP1 and CCP2, and a light scattering pattern layer LSP.

The bank BNK may be positioned on a top surface (e.g., upper surface) of the intermediate layer CTL to correspond to (or to overlap) the pixel defining layer PDL in the non-emission area NEA. The bank BNK may be a structure which defines a position of each of the first color conversion pattern layer CCP1, the second color conversion pattern layer CCP2, and the light scattering pattern layer LSP, thereby finally defining an emission area EMA of the first sub-pixel SPX1, an emission area EMA of the second sub-pixel SPX2, and an emission area EMA of the third sub-pixel SPX3. For example, the bank BNK may surround each of the first color conversion pattern layer CCP1, the second color conversion pattern layer CCP2, and the light scattering pattern layer LSP.

The bank BNK may include a light blocking material. For example, the bank BNK may be a black matrix, but embodiments are not limited thereto. In some embodiments, the bank BNK may include at least one light blocking material and/or at least one reflective material such that light emitted from each of the first color conversion pattern layer CCP1, the second color conversion pattern layer CCP2, and the light scattering pattern layer LSP may be transmitted in an image display direction of the display device DD, thereby improving the light emission efficiency of the pixel PXL.

The first color conversion pattern layer CCP1 may be positioned on the top surface (e.g., upper surface) of the intermediate layer to correspond to (or to overlap) the first light emitting element LD1. The first color conversion pattern layer CCP1 may include first color conversion particles QD1 distributed in a matrix material such as base resin. For example, the first color conversion particles QD1 may be red quantum dots. The first sub-pixel SPX1 may be a red sub-pixel. The first color conversion pattern layer CCP1 may be disposed in the emission area EMA of the first sub-pixel SPX1.

The second color conversion pattern layer CCP2 may be positioned on the top surface of the intermediate layer to correspond to (or to overlap) the second light emitting element LD2. The second color conversion pattern layer CCP2 may include second color conversion particles QD2 distributed in a matrix material such as base resin. For example, the second color conversion particles QD2 may be green quantum dots. The second sub-pixel SPX2 may be a green sub-pixel. The second color conversion pattern layer CCP2 may be disposed in the emission area EMA of the second sub-pixel SPX2.

The light scattering pattern layer LSP may be positioned on the top surface of the intermediate layer to correspond to (or to overlap) the third light emitting element LD3. The light scattering pattern layer LSP may include light scattering particles SCT distributed in a matrix material such as base resin. The light scattering pattern layer LSP may include light scattering particles SCT such as silica, but the material of the light scattering particles SCT is not limited thereto. In some embodiments, the light scattering particles SCT may be omitted, and the light scattering pattern layer LSP formed of transparent polymer may be provided. The third sub-pixel SPX3 may be a blue sub-pixel. The light scattering pattern layer LSP may be disposed in the emission area EMA of the third sub-pixel SPX3.

The second capping layer CPL2 may be positioned on a surface (e.g., lower surface) of the color conversion layer CCL (e.g., a surface facing the intermediate layer CTL), thereby protecting the color conversion layer CCL. For example, the second capping layer CPL2 may be an inorganic insulating layer including an inorganic material.

The color filter layer CFL may be disposed on the color conversion layer CCL. A first capping layer CPL1 may be disposed between the color filter layer CFL and the color conversion layer CCL.

The color filter layer CFL may be positioned between the base layer BSL and the color conversion layer CCL to face the display element layer DPL. The color filter layer CFL may include a color filter CF corresponding to each sub-pixel SPX. For example, the color filter layer CFL may include a first color filter CF1 disposed on the first color conversion pattern layer CCP1 of the first sub-pixel SPX1, a second color filter CF2 disposed on the second color conversion pattern layer CCP2 of the second sub-pixel SPX2, and a third color filter CF3 disposed on the light scattering pattern layer LSP of the third sub-pixel SPX3.

Each of the first, second, and third color filters CF1, CF2, and CF3 may include a colorant, such as a dye or a pigment, which absorbs wavelengths except a corresponding color wavelength. For example, the first color filter CF1 may be a red color filter which transmits red light therethrough and absorbs light of a wavelength range except the red light, the second color filter CF2 may be a green color filter which transmits green light therethrough and absorbs light of a wavelength range except the green light, and the third color filter CF3 may be a blue color filter which transmits blue light therethrough and absorbs light of a wavelength range except the blue light. Although a case where adjacent color filters CF are disposed to be spaced apart from each other with a light blocking pattern layer BM interposed therebetween is disclosed in the drawing, embodiments are not limited thereto. In some embodiments, adjacent color filters CF may at least partially overlap each other on the light blocking pattern layer BM, or may be disposed on the light blocking pattern layer BM to be spaced apart from each other. In other embodiments, adjacent color filters CF may be positioned to overlap each other in the non-emission area NEA. In another example, the light blocking pattern layer BM may be omitted.

For example, the color filter layer CFL may further include the light blocking pattern layer BM positioned between the first, second, and third color filters CF1, CF2, and CF3.

The light blocking pattern layer BM may be positioned on a surface of the base layer BSL to correspond to (or to overlap) the bank BNK and the pixel defining layer PDL. The light blocking pattern layer BM may include a light blocking material. For example, the light blocking pattern layer BM may be a black matrix, but embodiments are not limited thereto. The light blocking pattern layer BM and the bank BNK may include the same material. The light blocking pattern layer BM may be a structure for defining the emission area EMA of each of the first, second, and third sub-pixels SPX1, SPX2, and SPX3. The light blocking pattern layer BM may be positioned between adjacent color filters CF, thereby preventing color mixture of lights respectively emitted through the first, second, and third color filters CF1, CF2, and CF3.

The first capping layer CPL1 may be positioned between the color conversion layer CCL and the color filter layer CFL. The first capping layer CPL1 may cover a surface of the color filter layer CFL (e.g., a surface facing the color conversion layer CCL), thereby preventing an impurity such as moisture or air infiltrating from the outside from damaging or contaminating the color filter layer CFL. For example, the first capping layer CPL1 may prevent a colorant of the color filter layer CFL from being diffused (or permeated) into another component. The first capping layer CPL1 may be an inorganic insulating layer including an inorganic material.

The base layer BSL may be a rigid substrate or a flexible substrate, and the material or property of the base layer BSL is not limited. The base layer BSL may be formed of the same material as the substrate SUB or be formed of a material different from a material of the substrate SUB.

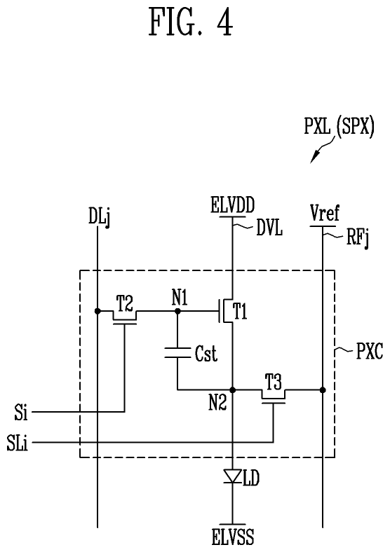

FIG. 4 is a circuit diagram schematically illustrating an electrical connection relationship of components included in each of the pixels PXL shown in FIG. 2.

Referring to FIGS. 1 to 4, the pixel PXL (or sub-pixel SPX) may include a light emitting element LD and a pixel circuit PXC electrically connected to the light emitting element LD to drive the light emitting element LD.

A first electrode of the light emitting element LD may be electrically connected to the pixel circuit PXC. The light emitting element LD generates light (or beam) with a certain luminance, corresponding to an amount of current supplied from the pixel circuit PXC.

For example, a second driving power source ELVSS may be set to a voltage lower than a voltage of a first driving power source ELVDD during a driving period of the display device DD, but embodiments are not limited thereto.

In case that the pixel PXL (or sub-pixel SPX) is positioned on an i-th row and a j-th column in the display area DA, the pixel circuit PXC of the pixel PXL (or sub-pixel SPX) may be electrically connected to an i-th scan line Si and a j-th data line DLj. For example, the pixel circuit PXC may be electrically connected to an i-th sensing line SLi and a j-th reference voltage line RFj.

The pixel circuit PXC may control an amount of current flowing from the first driving power source ELVDD to the second driving power source ELVSS via the light emitting element LD, corresponding to a data signal (or data voltage).

The pixel circuit PXC may include first, second, and third transistors T1, T2, and T3 and a storage capacitor Cst.

The first transistor T1 may be a driving transistor for controlling a driving current applied to the light emitting element LD, and may be electrically connected between the first driving power source ELVDD and the light emitting element LD. For example, a first terminal of the first transistor T1 may be electrically connected to the first driving power source ELVDD through a driving voltage line DVL, a second terminal of the first transistor T1 may be electrically connected to a second node, and a gate electrode of the first transistor T1 may be electrically connected to a first node N1. The first transistor T1 may control an amount of driving current applied from the first driving power source ELVDD to the light emitting element LD through the second node N2 according to a voltage applied to the first node N1. In an embodiment, the first terminal of the first transistor T1 may be a drain electrode, and the second terminal of the first transistor T1 may be a source electrode. However, embodiments are not limited thereto. In some embodiments, the first terminal may be the source electrode and the second terminal may be the drain electrode.

The second transistor T2 may be a switching transistor which selects a pixel PXL and activates the pixel PXL, and may be electrically connected between the j-th data line DLj and the first node N1. A first terminal of the second transistor T2 may be electrically connected to the j-th data line DLj, a second terminal of the second transistor T2 may be electrically connected to the first node N1, and a gate electrode of the second transistor T2 may be electrically connected to the i-th scan line Si. The first terminal and the second terminal of the second transistor T2 may be different terminals. For example, in case that the first terminal is a drain electrode, and the second terminal may be a source electrode.

Therefore, the second transistor T2 may be turned on in case that a scan signal having a gate-on voltage (e.g., a high level voltage) is supplied from the i-th scan line Si, to electrically connect the j-th data line DLj and the first node N1 to each other. The second transistor T2 may transfer a data signal to the gate electrode of the first transistor T1.

The third transistor T3 may be turned on in case that a sensing signal is supplied from the i-th sensing line SLi, to electrically connect the j-th reference voltage line RFj to the first transistor T1 (or the second node N2). A first terminal of the third transistor T3 may be electrically connected to the j-th reference voltage line RFj, a second terminal of the third transistor T3 may be electrically connected to the second node N2, and a gate electrode of the third transistor T3 may be electrically connected to the i-th sensing line SLi.

The third transistor T3 may be a sensing transistor operated to supply a reference voltage Vref transferred through the j-th reference voltage line RFj to the second node N2 or to sense a voltage or current of the second node N2 or the j-th reference voltage line RFj. The reference voltage Vref may be a voltage, e.g., a voltage of an initialization power source, which is lower than the voltage of the first driving power source ELVDD and/or the data voltage.

The storage capacitor Cst may include a first storage electrode and a second storage electrode. The first storage electrode of the storage capacitor Cst may be electrically connected to the first node N1, and the second storage electrode of the storage capacitor Cst may be electrically connected to the second node N2. The storage capacitor Cst may charge a data voltage corresponding to a data signal supplied to the first node N1 during one frame period. The storage capacitor Cst may store a voltage corresponding to a difference between a voltage of the gate electrode of the first transistor T1 and a voltage of the second node N2.

Although an embodiment in which the first, second, and third transistors T1, T2, and T3 included in the pixel circuit PXC are all implemented with an N-type transistor is disclosed in FIG. 4, embodiments are not limited thereto. For example, at least one of the first, second, and third transistors T1, T2, and T3 may be changed to a P-type transistor or an oxide transistor.

The structure of the pixel circuit PXC may be variously modified and embodied. For example, the pixel circuit PXC may additionally further include at least one transistor element such as a transistor element for initializing the first node N1 and/or a transistor element for controlling an emission time of the light emitting element LD, or other circuit elements such as a boosting capacitor for boosting a voltage of the first node N1.

In the following embodiment, for convenience of description, a lateral direction (or X-axis direction) on a plane is indicated as a first direction DR1, a longitudinal direction (or Y-axis direction) on the plane is indicated as a second direction DR2. A longitudinal direction on a section is indicated as the third direction DR3.

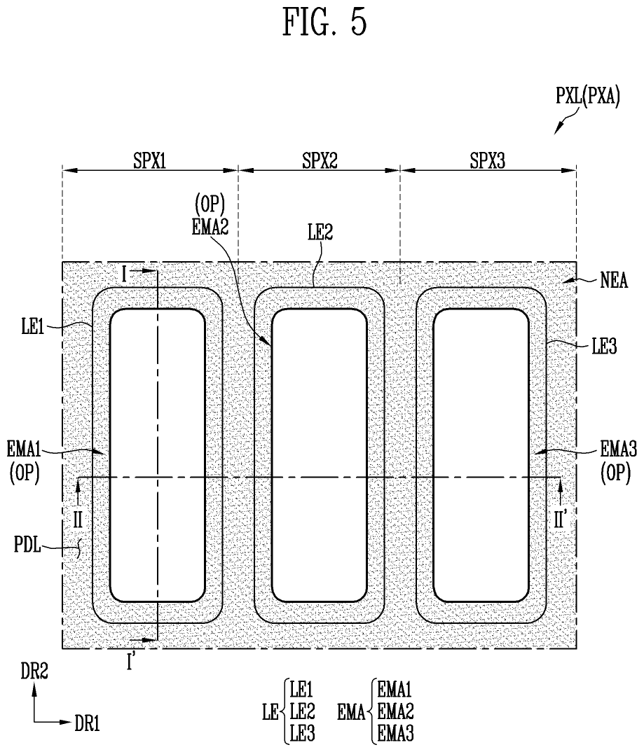

FIG. 5 is a schematic plan view illustrating a pixel PXL in accordance with an embodiment.

In FIG. 5, the pixel PXL may include not only components included in the pixel PXL but also an area in which the components are provided (or positioned).

Referring to FIGS. 1 to 5, the pixel PXL may be positioned in a pixel area PXA provided in the display area DA. The pixel area PXA may include an emission area EMA and a non-emission area NEA.

The pixel PXL may include a first sub-pixel SPX1 (or first pixel), a second sub-pixel SPX2 (or second pixel), and a third sub-pixel SPX3 (or third pixel).

The first sub-pixel SPX1 may include a first emission area EMA1 and the non-emission area NEA adjacent to the first emission area EMA1 (or surrounding at least one side of the first emission area EMA1). The second sub-pixel SPX2 may include a second emission area EMA2 and the non-emission area NEA adjacent to the second emission area EMA2 (or surrounding at least one side of the second emission area EMA2). The third sub-pixel SPX3 may include a third emission area EMA3 and the non-emission area NEA adjacent to the third emission area EMA3 (or surrounding at least one side of the third emission area EMA3). The first emission area EMA1, the second emission area EMA2, and the third emission area EMA3 may form the emission area EMA of the pixel PXL.

For example, the first sub-pixel SPX1 may be a red sub-pixel emitting red light, the second sub-pixel SPX2 may be a green sub-pixel emitting green light, and the third sub-pixel SPX3 may be a blue sub-pixel emitting blue light.

Each of the first, second, and third sub-pixels SPX1, SPX2, and SPX3 may include a light emitting element (see “LD” shown in FIG. 4) emitting light and a pixel circuit (see “PXC” shown in FIG. 4) for driving the light emitting element LD. The first emission area EMA1 may an area in which light is emitted from a light emitting element driven by a pixel circuit of the first sub-pixel SPX1 (or an area in which light passing through a color filter of the first sub-pixel SPX1 is emitted). The second emission area EMA2 may an area in which light is emitted from a light emitting element driven by a pixel circuit of the second sub-pixel SPX2 (or an area in which light passing through a color filter of the second sub-pixel SPX2 is emitted). The third emission area EMA3 may an area in which light is emitted from a light emitting element driven by a pixel circuit of the third sub-pixel SPX3 (or an area in which light passing through a color filter of the third sub-pixel SPX3 is emitted).

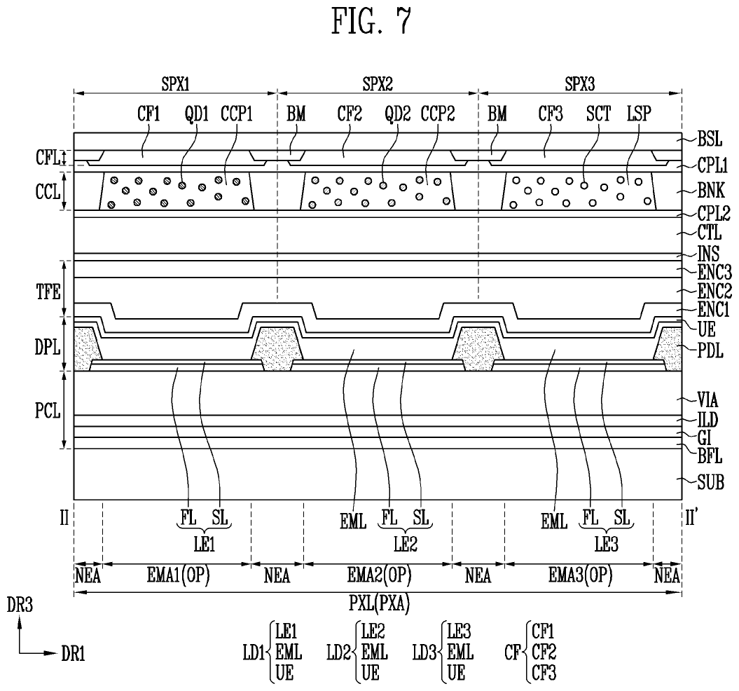

The light emitting element positioned in the first sub-pixel SPX1 may include a (1-1)th electrode LE1, an emission layer (see “EML” shown in FIG. 7) positioned on the (1-1)th electrode LE1, and a second electrode (see “UE” shown in FIG. 7) positioned on the emission layer EML. The light emitting element positioned in the second sub-pixel SPX2 may include a (1-2)th electrode LE2, an emission layer (see “EML” shown in FIG. 7) positioned on the (1-2)th electrode LE2, and a second electrode UE positioned on the emission layer EML. The light emitting element positioned in the third sub-pixel SPX3 may include a (1-3)th electrode LE3, an emission layer (see “EML” shown in FIG. 7) positioned on the (1-3)th electrode LE3, and a second electrode UE positioned on the emission layer EML.

The second electrode UE of the first sub-pixel SPX1, the second electrode UE of the second sub-pixel SPX2, and the second electrode UE of the third sub-pixel SPX3 may correspond to (or to overlap) a common layer commonly provided in adjacent sub-pixels SPX. The (1-1)th electrode LE1, the (1-2)th electrode LE2, and the (1-3)th electrode LE3 may form a first electrode LE of the pixel PXL.

The pixel PXL may include a pixel defining layer PDL which is disposed on the first electrode LE and includes an opening OP exposing a portion of the first electrode LE. For example, the pixel defining layer PDL may include an opening OP exposing each of a portion of the (1-1)th electrode LE1, a portion of the (1-2)th electrode LE2, and a portion of the (1-3)th electrode LE3. The opening OP of the pixel defining layer PDL may correspond to (or to overlap) each of the first, second, and third emission areas EMA1, EMA2, and EMA3.

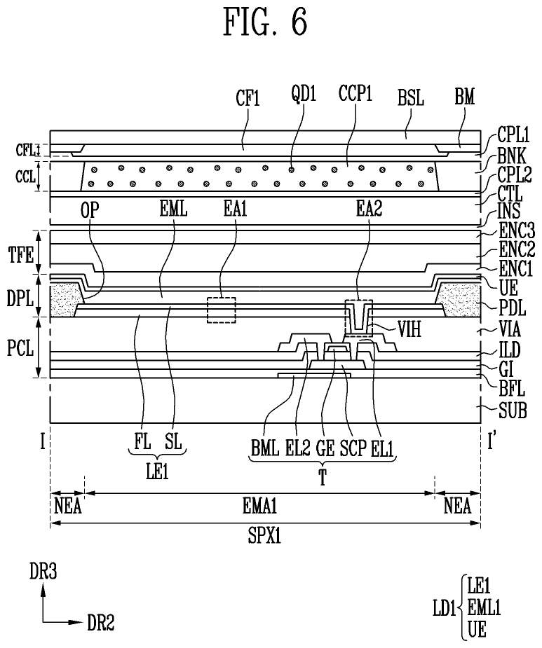

Hereinafter, a sectional structure (or stacked structure) of the pixel PXL in accordance with the above-described embodiment will be mainly described in detail with reference to FIGS. 6 to 11.

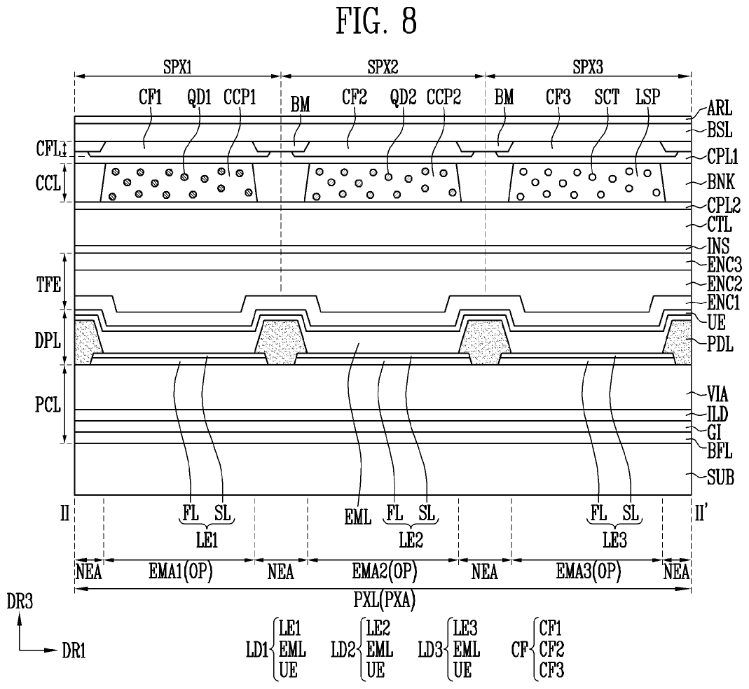

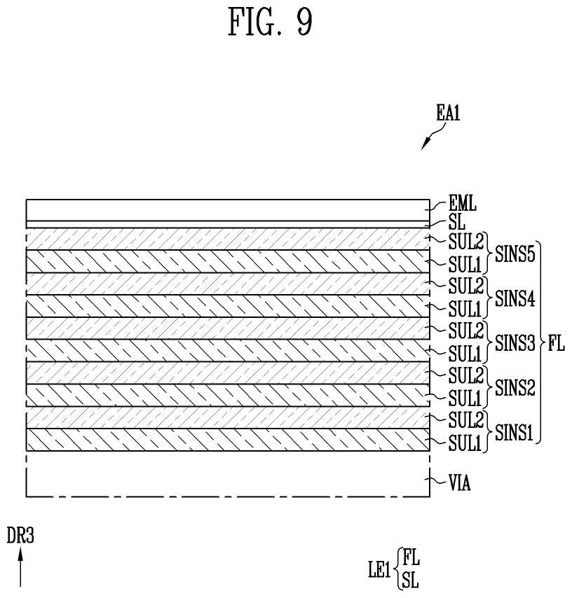

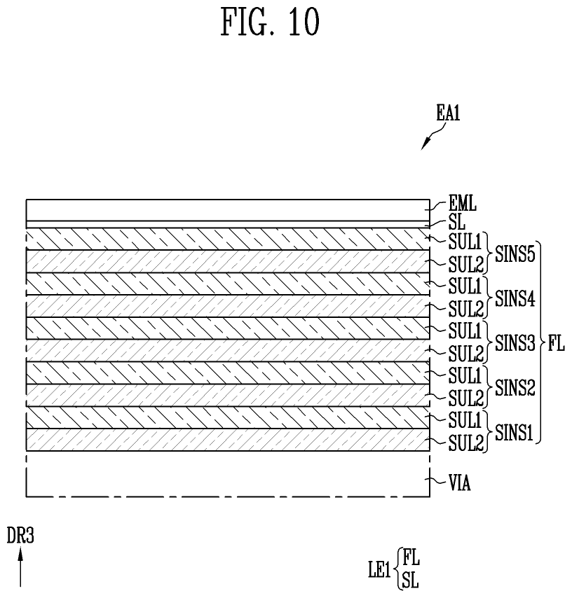

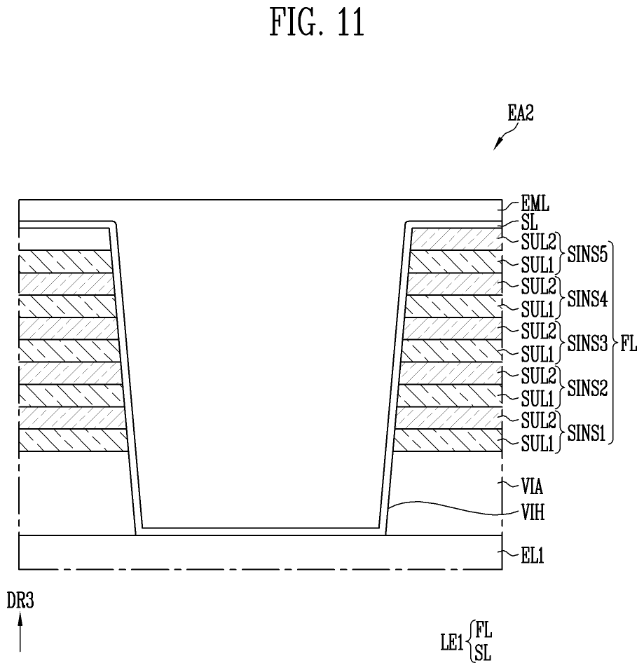

FIG. 6 is a schematic cross-sectional view taken along line I-I′ shown in FIG. 5. FIGS. 7 and 8 are schematic cross-sectional views taken along line II-II′ shown in FIG. 5. FIGS. 9 and 10 are schematic enlarged views illustrating portion EA1 shown in FIG. 6. FIG. 11 is a schematic enlarged view illustrating portion EA2 shown in FIG. 6.

In relation to the embodiment shown in FIGS. 6 to 11, portions different from the portions of the above-described embodiment will be mainly described to avoid redundancy.

Referring to FIGS. 1 to 11, each of the first, second, and third sub-pixels SPX1, SPX2, and SPX3 may include a substrate, a pixel circuit layer PCL, a display element layer DPL, and a thin film encapsulation layer TFE.

The pixel circuit layer PCL and the display element layer DPL may be disposed on a surface of the substrate SUB to overlap each other. For example, the pixel area PXA of the substrate SUB may include the pixel circuit layer PCL disposed on the surface of the substrate SUB and the display element layer DPL disposed on the pixel circuit layer PCL. However, the positions of the pixel circuit layer PCL and the display element layer DPL on the substrate SUB may vary in some embodiments.

The substrate SUB may include a transparent insulating material to transmit light therethrough. The substrate SUB may be a rigid substrate or a flexible substrate.

Circuit elements (e.g., a transistor T) forming the pixel circuit PXC of each of the first, second, and third sub-pixels SPX1, SPX2, and SPX3 and signal lines electrically connected to the circuit elements may be disposed in each pixel area PXA of the pixel circuit layer PCL. For example, a driving voltage line (see “DVL” shown in FIG. 4) may be disposed in each pixel area PXA of the pixel circuit layer PCL. A light emitting element LD electrically connected to the pixel circuit PXC of each of the first, second, and third sub-pixels SPX1, SPX2, and SPX3 may be disposed in each pixel area PXA of the display element layer DPL.

The pixel circuit layer PCL may include at least one insulating layer in addition to the circuit elements, the signal lines, and the driving voltage line DVL. For example, the pixel circuit layer PCL may include a buffer layer BFL, a gate insulating layer GI, an interlayer insulating layer ILD, and a via layer VIA, which are sequentially stacked on the substrate SUB along the third direction DR3.

The buffer layer BFL may be disposed (e.g., entirely disposed) on the substrate SUB. The buffer layer BFL may prevent an impurity from being diffused (or permeated) into the transistor T included in the pixel circuit PXC. The buffer layer BFL may be an inorganic insulating layer including an inorganic material. The buffer layer BFL may include at least one of silicon nitride (SiNₓ), silicon oxide (SiOₓ), silicon oxynitride (SiOₓN_{y}), and aluminum oxide (AlOₓ). The buffer layer BFL may be formed as a single layer, but be formed as a multi-layer including at least two layers. In case that the buffer layer BFL is formed as the multi-layer, the layers may be formed of the same material or be formed of different materials. The buffer layer BFL may be omitted according to a material of the substrate SUB, a process condition, and the like.

The gate insulating layer GI may be disposed (e.g., entirely disposed) on the buffer layer BFL. The gate insulating layer GI may include the same material as the above-described buffer layer BFL, or include an appropriate (or selected) material among the materials described as the material of the buffer layer BFL. For example, the gate insulating layer GI may be an inorganic insulting layer including an inorganic material.

The interlayer insulating layer ILD may be provided (e.g., entirely provided) and/or formed on the gate insulating layer GI. The interlayer insulating layer ILD may include the same material as the buffer layer BFL, or include an appropriate (or selected) material among the materials described as the material of the buffer layer BFL.

The via layer VIA may be provided (e.g., entirely provided) and/or formed on the interlayer insulating layer ILD. The via layer VIA may be an inorganic insulating layer including an inorganic material or an organic insulating layer including an organic material. The inorganic insulating layer may include, for example, at least one of silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin. In an embodiment, the via layer VIA may be an organic insulating layer including an organic material.

The via layer VIA may be partially opened to include a via hole VIH. The via hole VIH may be a connection point for electrically connecting a pixel circuit (see “PXC” shown in FIG. 4) and a light emitting element LD of each sub-pixel SPX to each other.

The pixel circuit PXC disposed in the pixel circuit layer PCL may include at least one transistor T. The transistor T may be a driving transistor for controlling a driving current of the light emitting element LD of each sub-pixel SPX. For example, the transistor T may be the first transistor T1 described with reference to FIG. 4.

The transistor T may include a semiconductor pattern layer SCP, a gate electrode GE, a first terminal EL1, and a second terminal EL2.

The gate electrode GE may be disposed on the gate insulating layer GI to be covered by the interlayer insulating layer ILD. For example, the gate electrode GE may be a gate conductive layer positioned between the gate insulating layer GI and the interlayer insulating layer ILD. The gate electrode GE may overlap a portion of the semiconductor pattern layer SCP. For example, the gate electrode GE may overlap an active pattern layer of the semiconductor pattern layer SCP.

The semiconductor pattern layer SCP may be provided and/or formed on the buffer layer BFL. For example, the semiconductor pattern layer SCP may be positioned between the buffer layer BFL and the gate insulating layer GI. The semiconductor pattern layer SCP may be a semiconductor layer made of poly-silicon, amorphous silicon, an oxide semiconductor, or the like. The semiconductor pattern layer SCP may include an active pattern layer, a first contact region, and a second contact region. The active pattern layer, the first contact region, and the second contact region may be formed as a semiconductor layer undoped or doped with an impurity. For example, the first contact region and the second contact region may be formed as a semiconductor layer doped with the impurity, and the active pattern layer may be formed as a semiconductor layer undoped with the impurity. The impurity may include, for example, an n-type impurity, but embodiments are not limited thereto.

The active pattern layer of the semiconductor pattern layer SCP may be a region overlapping the gate electrode GE of the transistor T, and may be a channel region. The first contact region of the semiconductor pattern layer SCP may be in contact with an end portion of the active pattern layer. For example, the first contact region may be electrically connected to the first terminal EL1. The second contact region of the semiconductor pattern layer SCP may be in contact with another end portion of the active pattern layer. For example, the second contact region may be electrically connected to the second terminal EL2.

The first terminal EL1 may be provided and/or formed on the interlayer insulating layer ILD. For example, the first terminal EL1 may be formed as a source-drain conductive layer formed between the interlayer insulating layer ILD and the via layer VIA. The first terminal EL1 may be in contact with the first contact region of the semiconductor pattern layer SCP through a contact hole penetrating the gate insulating layer GI and the interlayer insulating layer ILD.

The second terminal EL2 may be provided and/or formed on the interlayer insulating layer ILD, and may be disposed to be spaced apart from the first terminal EL1.

The second terminal EL2 may be formed as a source-drain conductive layer formed between the interlayer insulating layer ILD and the via layer VIA. The second terminal EL2 may be in contact with the second contact region of the semiconductor pattern layer SCP through another contact hole penetrating the gate insulating layer GI and the interlayer insulating layer ILD.

A bottom metal pattern layer BML may be disposed under the above-described transistor T.

The bottom metal pattern layer BML may be a first conductive layer positioned between the substrate SUB and the buffer layer BFL. The bottom metal pattern layer BML may be electrically connected to the transistor T, to broaden the driving range of a voltage supplied to the gate electrode GE of the transistor T. For example, the bottom metal pattern layer BML may be electrically connected to the transistor T, to stabilize (or protect) the channel region of the transistor T. For example, as the bottom metal pattern layer BML is electrically connected to the transistor T, floating of the bottom metal pattern layer BML may be prevented.

In the above-described embodiment, a case where the transistor T is a thin film transistor having a top-gate structure has been illustrated as an example. However, embodiments are not limited thereto, and the structure of the transistor T may be variously modified.

The via layer VIA may be disposed over the transistor T. The via layer VIA may expose a portion (e.g., the first terminal EL1) of a transistor T of a corresponding sub-pixel SPX through the via hole VIH. In the first sub-pixel SPX1, the first terminal EL1 of the transistor T, which is exposed through the via hole VIH, may be electrically connected to a (1-1)th electrode LE1. In the second sub-pixel SPX2, a transistor exposed through a via hole of the via layer VIA may be electrically connected to a (1-2)th electrode LE2. In the third sub-pixel SPX3, a transistor exposed through a via hole of the via layer VIA may be electrically connected to a (1-3)th electrode LE3.

The display element layer DPL may be positioned on the via layer VIA.

The display element layer DPL may include first, second, and third light emitting elements LD1, LD2, and LD3 and a pixel defining layer PDL.

The first light emitting element LD1 may include the (1-1)th electrode LE1, an emission layer EML, and a second electrode UE. The second light emitting element LD2 may include the (1-2)th electrode LE2, an emission layer EML, and a second electrode UE. The third light emitting element LD3 may include the (1-3)th electrode LE3, an emission layer EML, and a second electrode UE. Each of the first, second, and third light emitting elements LD1, LD2, and LD3 may be electrically connected to a transistor of a corresponding sub-pixel SPX.

Each of the (1-1)th electrode LE1, the (1-2)th electrode LE2, and the (1-3)th electrode LE3 may be provided and/or formed on the via layer VIA of a corresponding sub-pixel SPX. The (1-1)th electrode LE1, the (1-2)th electrode LE2, and the (1-3)th electrode LE3 may be disposed on the via layer VIA to be spaced apart from each other. The (1-1)th electrode LE1 may be an anode of the first light emitting element LD1, the (1-2)th electrode LE2 may be an anode of the second light emitting element LD2, and the (1-3)th electrode LE3 may be an anode of the third light emitting element LD3.

In an embodiment, each of the (1-1)th electrode LE1, the (1-2)th electrode LE2, and the (1-3)th electrode LE3 may include a first layer FL and a second layer SL, which are stacked along the third direction DR3.

The first layer FL may include at least one sub-insulating layer including a first sub-layer SUL1 and a second sub-layer SUL2, which are sequentially stacked and have different refractive indices. For example, the first layer FL may include first, second, third, fourth, and fifth sub-insulating layers SINS1, SINS2, SINS3, SINS4, and SINS5 as shown in FIGS. 9 and 10. Each of the first to fifth sub-insulating layers SINS1 to SINS5 may include a first sub-layer SUL1 and a second sub-layer SUL2, which are sequentially stacked along the third direction DR3.

The first sub-layer SUL1 may include a first inorganic layer having a first refractive index, and the second sub-layer SUL2 may include a second inorganic layer having a second refractive index different from the first refractive index. The first refractive index may be smaller than the second refractive index. For example, the first sub-layer SUL1 may include silica doped with fluorine, carbon or the like. For example, the first sub-layer SUL1 may include SiOCF:H. The first sub-layer SUL1 may have a refractive index of about 1.4 or less. The second sub-layer SUL2 may include niobium oxide (Nb₂O₅). The second sub-layer SUL2 may have a refractive index of about 2.3 or less.

The above-described first layer FL may include a distributed Bragg reflection layer in which the first sub-layer SUL1 having the first refractive index and the second sub-layer SUL2 having the second refractive index are alternately and repeatedly stacked with each other. For example, the first layer FL may include at least one sub-insulating layer such that the first sub-layer SUL1 having the first refractive index and the second sub-layer SUL2 having the second refractive index may be stacked with each other.

Each of the first to fifth sub-insulating layers SINS1 to SINS5 may include a first sub-layer SUL1 and a second sub-layer SUL2 disposed on the first sub-layer SUL1 in the third direction DR3. The first layer FL may include a distributed Bragg reflection layer in which the first sub-layer SUL1 having a low refractive index and the second sub-layer SUL2 having a high refractive index are alternately and repeatedly stacked with each other. However, embodiments are not limited thereto. In some embodiments, as shown in FIG. 10, each of the first to fifth sub-insulating layers SINS1 to SINS5 may include a second sub-layer SUL2 and a first sub-layer SUL1 disposed on the second sub-layer SUL2 in the third direction DR3. The first layer FL may include a distributed Bragg reflection layer in which the second sub-layer SUL2 having a high refractive index and the first sub-layer SUL1 having a low refractive index are alternately and repeatedly stacked with each other.

The above-described first layer FL may reflect light, which transmits toward a back surface of an emission layer EML of each of the first, second, and third sub-pixels SPX1, SPX2, and SPX3, e.g., the pixel circuit layer PCL (or the via layer VIA), in a direction (e.g., the image display direction of the display device DD). As described above, as the first sub-layer SUL1 and the second sub-layer SUL2, which have different refractive indices, are alternately stacked, to form the first layer FL, a refractive index difference is repeatedly formed in the first layer FL, so that light incident onto the first layer FL may have different transmittances according to an incident angle thereof. The material, thickness, and/or stacked number of each of stacked first and second sub-layers SUL1 and SUL2 may be adjusted, so that the reflexibility of light incident onto the first layer FL may be optimally increased. The thickness of each of the first and second sub-layers SUL1 and SUL2 may be adjusted according to the wavelength and refractive index of light. In case that the refractive index of a stacked layer (e.g., inorganic layer) is n, and the wavelength of light to be reflected is λ, a low refractive layer (or high refractive layer) and a high refractive layer (or low refractive layer), which have a thickness of λ/4n, are alternately stacked, light having a specific wavelength range, e.g., blue wavelength range may be effectively reflected.

In an embodiment, the second layer SL may be disposed on the first layer FL. The second layer SL may be pixel circuit PXC through the via hole VIH. For example, in the first sub-pixel SPX1, the second layer SL may be electrically connected to the first terminal EL1 of the transistor T of the pixel circuit PXC through the via hole VIH. The first layer FL may not be positioned in the via hole VIH. In an embodiment, only the second layer SL may be positioned in the via hole VIH. Accordingly, the second layer SL positioned on the first layer FL may be in contact with (e.g., in direct contact with) the first terminal EL1 of the transistor T, which is exposed by the via hole VIH, and penetrates the via hole VIH, thereby being electrically and physically connected to the first terminal EL1 of the transistor T.

The second layer SL may include a transparent conductive material. For example, the second layer SL may include at least one of indium tin oxide (ITO) and tungsten oxide. In some embodiments, the second layer SL may control a hole injection amount of an emission layer EML of each of the first, second, and third sub-pixels SPX1, SPX2, and SPX3, thereby increasing an electron-hole recombination rate in the corresponding emission layer. In case that the second layer SL includes the tungsten oxide, the second layer SL has a relatively low resistance and excellent step coverage as compared with a case that the second layer SL includes the ITO, so that a leakage current caused by surface roughness or the like may be reduced.

As described above, each of the (1-1)th electrode LE1, the (1-2)th electrode LE2, and (1-3)th electrode LE3 may be formed to include a first layer FL disposed on the via layer VIA along the third direction DR3 and a second layer SL disposed on the first layer FL. The (1-1)th electrode LE1 may be in at least a first emission area EMA1, the (1-2)th electrode LE2 may be positioned in at least a second emission area EMA2, and the (1-3)th electrode EL3 may be positioned in at least a third emission area EMA3.

A pixel defining layer PDL may be disposed on the (1-1)th electrode LE1, the (1-2)th electrode LE2, the (1-3)th electrode LE3, and the via layer VIA.

The pixel defining layer PDL may be positioned in the non-emission area NEA, and may include openings OP which exposes a portion of the (1-1)th electrode LE1 in at least the first emission area EMA1, exposes a portion of the (1-2)th electrode LE2 in at least the second emission area EMA2, and exposes a portion of the (1-3)th electrode LE3 in at least the third emission area EMA3.

The pixel defining layer PDL may be formed as an organic insulating layer including an organic material. The organic material may include acrylic resin, epoxy resin, phenolic resin, polyamide resin, polyimide resin, and the like. In some embodiments, the pixel defining layer PDL may include a light absorption material or may include a light absorber coated thereon, to absorb light introduced from the outside. For example, the pixel defining layer PDL may include a carbon-based black pigment. However, embodiments are not limited thereto.

The pixel defining layer PDL may protrude in the third direction DR3 from the via layer VIA.

An emission layer EML may be disposed on the (1-1)th electrode LE1 exposed by an opening OP of the pixel defining layer PDL, the (1-2)th electrode LE2 exposed by another opening OP of the pixel defining layer PDL, and the (1-3)th electrode LE3 exposed by still another opening OP of the pixel defining layer PDL.

The emission layer EML may be disposed on the (1-1)th, (1-2)th, and (1-3)th electrodes LE1, LE2, and LE3 exposed by the openings OP of the pixel defining layer PDL. For example, the emission layer EML may be a common layer commonly provided in the first, second, and third sub-pixels SPX1, SPX2, and SPX3.

The emission layer EML may have a multi-layer thin film structure including a light generation layer for generating light. For example, the emission layer EML may include a hole injection layer for injecting holes, a hole transport layer for increasing a hole recombination opportunity by suppressing movement of electrons which are excellent in transportability of holes and are not combined in a light generation layer, the light generation layer for emitting light by recombination of the injected electrons and holes, a hole blocking layer for suppressing the movement of the holes that are not combined in the light generation layer, an electron transport layer for smoothly transporting the electrons to the light generation layer, and an electron injection layer for injecting the electrons. However, embodiments are not limited thereto.

In an embodiment, the emission layer EML may emit blue-based light.

A second electrode UE may be disposed on the emission layer EML.

The second electrode UE may be a common layer commonly provided in the first, second, and third sub-pixels SPX1, SPX2, and SPX3. The second electrode UE may be provided in a plate shape throughout the whole of the display area DA.

The second electrode UE may be a thin metal layer having a thickness to a degree to which light emitted from the emission layer EML of each of the first, second, and third sub-pixels SPX1, SPX2, and SPX3 may be transmitted therethrough. The second electrode UE may be formed of a metal material to have a relatively thin thickness or be formed of a transparent conductive material. For example, the second electrode UE may be formed of various transparent conductive materials. The second electrode UE may include at least one of various transparent conductive materials including indium tin oxide, indium zinc oxide, indium tin zinc oxide, aluminum zinc oxide, gallium zinc oxide, zinc tin oxide, and gallium tin oxide, and may be formed substantially transparent or translucent to satisfy a certain transmittance. Accordingly, light emitted from the emission layer EML positioned on the bottom surface of the second electrode UE may be emitted upwardly from the thin film encapsulating layer TFE to pass through the second electrode UE.

The thin film encapsulation layer TFE may be provided (e.g., entirely provided) and/or formed on the second electrode UE.

The thin film encapsulation layer TFE may include first, second, and third encapsulation layers ENC1, ENC2, and ENC3 sequentially positioned on the second electrode UE. The first encapsulation layer ENC1 may be positioned on the display element layer DPL, thereby being positioned throughout the display area DA and at least a portion of the non-display area NDA. The second encapsulation layer ENC2 may be positioned on the first encapsulation layer ENC1, thereby being positioned throughout the display area DA and at least a portion of the non-display area NDA. The third encapsulation layer ENC3 may be positioned on the second encapsulation layer ENC2, thereby being positioned throughout the display area DA and at least a portion of the non-display area NDA. In some embodiments, the third encapsulation layer ENC3 may be positioned throughout the whole of the display area DA and the non-display area NDA.

In an embodiment, each of the first and third encapsulation layers ENC1 and ENC3 may be formed as an inorganic layer including an inorganic material, and the second encapsulation layer ENC2 may be formed as an organic layer including an organic material. The inorganic layer may include, for example, silicon nitride (SiNₓ), silicon oxide (SiOₓ), silicon oxynitride (SiOₓN_{y}), or the like. The organic layer may include an organic insulating material such as acrylic resin, epoxy resin, phenolic resin, polyamides resin, polyimides resin, polyester resin, poly-phenylene sulfide resin, or benzocyclobutene (BCB).

The pixel PXL in accordance with an embodiment may further include an upper substrate disposed on the thin film encapsulation layer TFE. An intermediate layer CTL may be disposed between the thin film encapsulation layer TFE and the upper substrate. The upper substrate may be positioned on the thin film encapsulation layer TFE (or coupled to the thin film encapsulation layer TFE) by an adhesion process or the like.

An insulating layer INS formed as an inorganic insulating layer including an inorganic material may be disposed on the thin film encapsulation layer TFE. In some embodiments, the insulating layer INS may be the third encapsulation layer ENC3 positioned in an uppermost layer of the thin film encapsulation layer TFE.

The intermediate layer CTL may be provided and/or formed on the insulating layer INS. The intermediate layer CTL may include an adhesive material for reinforcing adhesion between the thin film encapsulation layer TFE and the upper substrate. The insulating layer INS may include a filler formed of an insulating material having insulative and adhesive properties. In some embodiments, the intermediate layer CTL may be used as a planarization layer for reducing a step difference caused by components positioned on the bottom surface of the intermediate layer CTL.

The upper substrate may be positioned on the intermediate layer CTL. The upper substrate may include a color filter layer CFL and a color conversion layer CCL, which are formed on a surface of a base layer BSL (e.g., a surface facing the thin film encapsulation layer TFE) by a continuous process. The upper substrate may be coupled to the thin film encapsulation layer TFE through the intermediate layer CTL. The upper substrate may include the base layer BSL, the color filter layer CFL, a first capping layer CPL1, the color conversion layer CCL, and a second capping layer CPL2.

The base layer BSL may be a rigid substrate or a flexible substrate, and the material or property of the base layer BSL is not limited. The base layer BSL and the substrate SUB may be formed of the same material or be formed of different materials, respectively.

The color filter layer CFL may be provided and/or formed on the surface (e.g., lower surface) of the base layer BSL.

The color filter layer CFL may include a first color filter CF1, a second color filter CF2, a third color filter CF3, and a light blocking pattern layer BM positioned between adjacent color filters CF.

The first color filter CF1 may be a red color filter, and be positioned on the surface of the base layer BSL to correspond to (or to overlap) a first color conversion pattern layer CCP1. The second color filter CF2 may be a green color filter, and be positioned on the surface of the base layer BSL to correspond to (or to overlap) a second color conversion pattern layer CCP2. The third color filter CF3 may be a blue color filter, and be positioned on the surface of the base layer BSL to correspond to (or to overlap) a light scattering pattern layer LSP.

The light blocking pattern layer BM may be positioned on the surface of the base layer BSL to correspond to (or to overlap) a bank BNK. The light blocking pattern layer BM may include a light blocking material for preventing a light leakage defect in which light is leaked between each of the first, second, and third emission areas EMA1, EMA2, and EMA3 and emission areas adjacent thereto. For example, the light blocking pattern layer BM may prevent color mixture of lights respectively emitted from the first, second, and third sub-pixels SPX1, SPX2, and SPX3 positioned adjacent to each other.

The first capping layer CPL1 may be provided and/or formed on the color filter layer CFL in the opposite direction of the third direction DR3. The first capping layer CPL1 may be used as a protective layer for protecting the color filter layer CFL by covering the color filter layer CFL, but embodiments are not limited thereto. The first capping layer CPL may be an inorganic insulating layer including an inorganic material or an organic insulating layer including an organic material. In some embodiments, the first capping layer CPL1 may be omitted.

The color conversion layer CCL may be provided and/or formed on a surface of the first capping layer CPL1 (e.g., a surface facing the thin film encapsulation layer TFE).

The color conversion layer CCL may include the first color conversion pattern layer CCP1, the second color conversion pattern layer CCP2, the light scattering pattern layer LSP, and the bank BNK.

The first color conversion pattern layer CCP1 may be positioned on the surface of the first capping layer CPL1 to correspond to (or to overlap) the emission layer EML in the first sub-pixel SPX1, and may include first color conversion particles QD1 for converting light emitted from the emission layer EML, e.g., blue-based light into red-based light (or light of a specific color).

The second color conversion pattern layer CCP2 may be positioned on the surface of the first capping layer CPL1 to correspond to (or to overlap) the emission layer EML in the second sub-pixel SPX2, and may include second color conversion particles QD2 for converting light emitted from the emission layer EML, e.g., blue-based light into green-based light (or light of a specific color).

The light scattering pattern layer LSP may be positioned on the surface of the first capping layer CPL1 to correspond to (or to overlap) the emission layer EML in the third sub-pixel SPX3, and be a transparent layer (or transparent window) for transmitting light emitted from the emission layer EML, e.g., blue-based light therethrough. The light scattering pattern layer LSP may include light scattering particles SCT for scattering blue-based light emitted from the emission layer EML in various directions.

The bank BNK may be positioned on the surface of the first capping layer CPL1 to correspond to (or to overlap) the pixel defining layer PDL. The bank BNK may be a structure defining a formation position of the first color conversion pattern layer CCP1, a formation position of the second color conversion pattern layer CCP2, and a formation position of the light scattering pattern layer LSP.

The bank BNK may include at least one light blocking material and/or a reflective material (or light scattering material). In some embodiments, the bank BNK may include a transparent material (or substance). The transparent material may include polyamide resin, polyimide resin, and the like, but embodiments are not limited thereto. In other embodiments, a reflective material layer may be separately provided and/or formed on the bank BNK so as to further improve the efficiency of light emitted from each of the first, second, and third sub-pixels SPX1, SPX2, and SPX3.

The second capping layer CPL2 may be provided and/or formed on the surface of the color conversion layer CCL in the opposite direction of the third direction DR3. In an embodiment, the second capping layer CPL2 may be used as a protective layer for protecting the color conversion layer CCL by covering the color conversion layer CCL, but embodiments are not limited thereto. The second capping layer CPL2 may be an inorganic insulating layer including an inorganic material or an organic insulating layer including an organic material.

As described above, as the color conversion layer CCL and the color filter layer CFL are disposed on the top surface of the thin film encapsulation layer TFE, light emitted from the emission layer EML of each of the first, second, and third sub-pixels SPX1, SPX2, and SPX3 may be converted into light having excellent color reproducibility and released, so that the light emission efficiency of each of the first, second, and third sub-pixels SPX1, SPX2, and SPX3 may be further improved.

In some embodiments, as shown in FIG. 8, an anti-reflective layer ARL may be disposed on another surface of the base layer BSL (e.g., an upper surface or a surface on which the color filter layer CFL is not positioned).

The anti-reflective layer ARL may be positioned in an uppermost layer of the display device DD, thereby reducing external light reflection. For example, the anti-reflective layer ARL may include a polarizing film and/or a phase retardation film. The number of phase retardation films and a phase retardation length of the phase retardation film may be determined according to an operation principle of the anti-reflective layer ARL. In some embodiments, the anti-reflective layer ARL may be used as an encapsulation layer for preventing external moisture, external oxygen, and the like from being introduced (or permeated) into the substrate SUB (or the display panel DP).

In the above-described embodiment, it has been described that the upper substrate including the color filter layer CFL and the color conversion layer CCL, which are formed on the surface of the base layer BSL by a continuous process, is disposed on the top surface of the thin film encapsulation layer TFE by an adhesion process or the like. However, embodiments are not limited thereto.

In accordance with the above-described embodiment, as each of the (1-1)th electrode LE1, the (1-2)th electrode LE2, and the (1-3)th electrode LE3, which corresponds to an anode of each of the first, second, and third light emitting elements LD1, LD2, and LD3, includes a first layer FL including a distributed Bragg reflection layer in which a first sub-layer SUL1 having a first refractive index and a second sub-layer SUL2 having a second refractive index are alternately and repeatedly stacked, light transmitting toward a back surface of an emission layer EML of each of the first, second, and third sub-pixels SPX1, SPX2, and SPX3 may be reflected to the second electrode UE by using a refractive index difference between the first sub-layer SUL1 and the second sub-layer SUL2, so that loss of light may be minimized. Accordingly, the light emission efficiency of each of the first, second, and third sub-pixels SPX1, SPX2, and SPX3 may be improved.

In accordance with the above-described embodiment, as each of the (1-1)th electrode LE1, the (1-2)th electrode LE2, and the (1-3)th electrode LE3 includes the first layer FL and a second layer SL which is positioned on the first layer FL and includes at least one of indium tin oxide and tungsten oxide, an Ag metal layer may not be applied to each of the (1-1)th electrode LE1, the (1-2)th electrode LE2, and the (1-3)th electrode LE3. Accordingly, Ag (silver) eruption which is occurred by applying the Ag metal layer is prevented, so that the reliability of each of the (1-1)th electrode LE1, the (1-2)th electrode LE2, and the (1-3)th electrode LE3 may be improved.

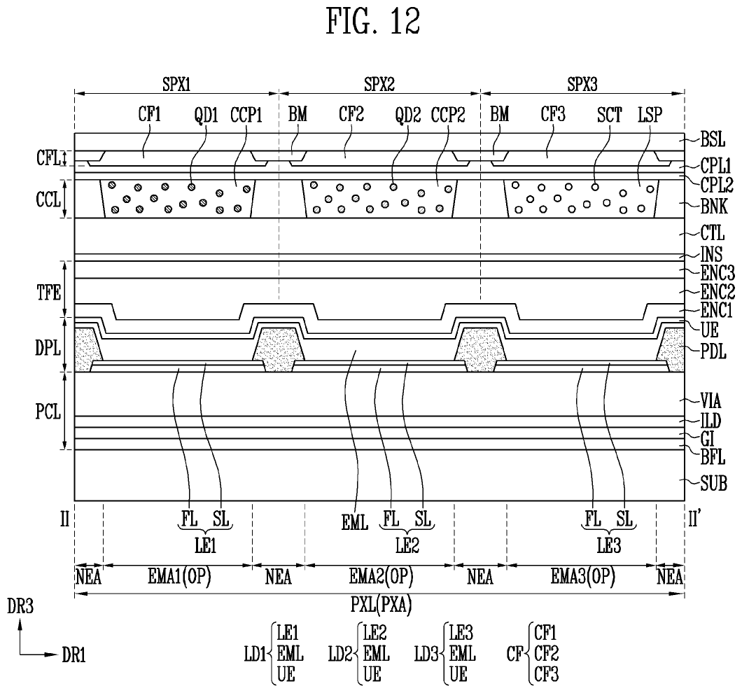

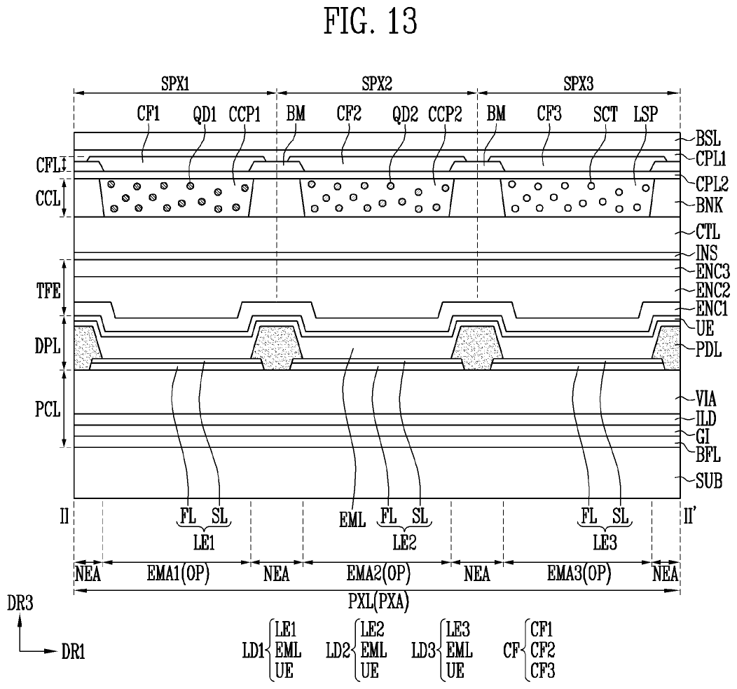

FIGS. 12 and 13 illustrate a pixel PXL in accordance with an embodiment, and are schematic cross-sectional views taken along the line II-II′ shown in FIG. 5.

Embodiments shown in FIGS. 12 and 13 illustrate different modified examples of FIG. 7 in relation to a position of a color conversion layer CCL. For example, an embodiment in which a color conversion layer CCL is formed on an intermediate layer CTL by a continuous process, and a separate substrate (e.g., an upper substrate) including a color filter layer CFL and base layer BSL is positioned on the surface of the color conversion layer CCL by an adhesion process is disclosed in FIG. 12, and an embodiment in which a color conversion layer CCL and a color filter layer CFL are continuously formed on an intermediate layer CTL is disclosed in FIG. 13.

In relation to the embodiments shown in FIGS. 12 and 13, portions different from those of the above-described embodiment will be mainly described to avoid redundancy.

First, referring to FIGS. 1 and 12, a pixel in accordance with an embodiment may include a color conversion layer CCL formed on an intermediate layer CTL by a continuous process. An upper substrate including a base layer BSL and a color filter layer CFL may be positioned on the top surface of the color conversion layer CCL. A bank BNK may be formed on a surface (e.g., upper surface) of the intermediate layer CTL to correspond to (or to overlap) a pixel defining layer PDL, and a first color conversion pattern layer CCP1, a second color conversion pattern layer CCP2, and a light scattering pattern layer LSP may be formed on the surface of the intermediate layer CTL to correspond to (or to overlap) an emission layer EML of each of first, second, and third sub-pixels SPX1, SPX2, and SPX3. For example, a second capping layer CPL2 may be formed on the bank BNK, the first color conversion pattern layer CCP1, the second color conversion pattern layer CCP2, and the light scattering pattern layer LSP. The second capping layer CPL2 may include an insulating material having insulative and adhesive properties so as to reinforce adhesion between the color conversion layer CCL and the upper substrate. The upper substrate may be disposed on the above-described second capping layer CPL2. The upper substrate may include the base layer BSL, the color filter layer CFL, and a first capping layer CPL1, which are sequentially stacked in the opposite direction of the third direction DR3. The first capping layer CPL1 may face the second capping layer CPL2.

Referring to FIGS. 1 and 13, a color conversion layer CCL may be formed on a surface (e.g., upper surface) of an intermediate layer CTL by a continuous process. A second capping layer CPL2 may be provided and/or formed on a surface of the color conversion layer CCL. A color filter layer CFL may be formed on the second capping layer CPL2 by a continuous process. A first capping layer CPL1 may be provided and/or formed on the color filter layer CFL. A base layer BSL may be provided and or formed on the first capping layer CPL1. The base layer BSL may be an inorganic insulating layer including an inorganic material, and may prevent external moisture, external oxygen, and the like from being introduced into the color filter layer CFL.

In accordance with the disclosure, a first electrode (or anode) including a first layer formed as a distributed Bragg reflection layer and a second layer which is positioned on the first layer and includes a transparent conductive material is disposed between an emission layer and a via layer (or pixel circuit layer), thereby reflecting light transmitting toward the via layer from the emission layer in a front direction. Thus, the light emission efficiency of a pixel may be improved, and accordingly, the luminance of the pixel may be increased.

In accordance with the disclosure, as the first electrode is formed as the above-described first and second layers without using an Ag metal layer, a defect (e.g., Ag eruption) which is occurred in application of the Ag metal layer may be prevented, thereby improving the reliability of the first electrode.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A pixel comprising:
a via layer disposed on a substrate;
a first electrode disposed on the via layer;
a pixel defining layer disposed on the first electrode, the pixel defining layer including an opening exposing a portion of the first electrode;
an emission layer disposed on the portion of the first electrode and the pixel defining layer; and
a second electrode disposed on the emission layer, wherein
the first electrode includes:
a first layer disposed on the via layer, and
a second layer disposed between the first layer and the pixel defining layer,
the first layer includes a plurality of sub-insulating layers, each of the plurality of sub-insulating layers including a first sub-layer and a second sub-layer that are sequentially stacked, and
the first sub-layer and the second sub-layer have different refractive indices.

2. The pixel of claim 1, wherein the first layer includes a Bragg reflection layer to reflect light toward the second layer, the light that is emitted from the emission layer and transmitted toward the via layer.

3. The pixel of claim 2, wherein
the first sub-layer includes a first inorganic layer having a first refractive index, and
the second sub-layer includes a second inorganic layer having a second refractive index.

4. The pixel of claim 3, wherein
the first refractive index is smaller than the second refractive index,
the first inorganic layer includes SiOCF:H, and
the second inorganic layer includes Nb₂O₅.

5. The pixel of claim 4, wherein the second layer includes a transparent conductive material.

6. The pixel of claim 5, wherein the second layer includes at least one of indium tin oxide and tungsten oxide.

7. The pixel of claim 5, further comprising:
at least one transistor disposed between the substrate and the via layer, wherein
the via layer includes a via hole exposing a portion of the at least one transistor, and
the second layer is electrically connected to the at least one transistor through the via hole.

8. The pixel of claim 7, wherein the first layer is not disposed in the via hole.

9. The pixel of claim 2, further comprising:
a thin film encapsulation layer disposed on the second electrode, wherein
the thin film encapsulation layer includes:
a first encapsulation layer disposed on the second electrode,
a second encapsulation layer disposed on the first encapsulation layer, and
a third encapsulation layer disposed on the second encapsulation layer,
the first encapsulation layer and the third encapsulation layer include an inorganic layer, and
the second encapsulation layer includes an organic layer.

10. The pixel of claim 9, further comprising:
a color conversion layer disposed on the thin film encapsulation layer; and
a color filter layer disposed on the color conversion layer.

11. The pixel of claim 10, wherein the color conversion layer includes:
a bank disposed on an upper surface of the thin film encapsulation layer and overlapping the pixel defining layer; and
a color conversion pattern layer disposed on the upper surface of the thin film encapsulation layer, the color conversion pattern layer being surrounded by the bank and converting light emitted from the emission layer into light of a specific color.

12. The pixel of claim 11, wherein the color filter layer includes:
a color filter disposed on the color conversion pattern layer; and
a light blocking pattern layer disposed adjacent to the color filter, the light blocking pattern layer disposed in a non-emission area.

13. The pixel of claim 12, wherein the light blocking pattern layer includes a black matrix.

14. The pixel of claim 12, further comprising:
an intermediate layer disposed between the thin film encapsulation layer and the color conversion layer,
wherein the intermediate layer includes an adhesive material.

15. The pixel of claim 14, further comprising:
a first capping layer disposed between the color conversion layer and the color filter layer;
a second capping layer disposed between the intermediate layer and the color conversion layer; and
a base layer disposed on an upper surface of the color filter layer.

16. The pixel of claim 15, further comprising:
an anti-reflection layer disposed on the base layer.

17. The pixel of claim 1, wherein the emission layer is configured to emit blue-based light.

18. A display device comprising:
a substrate including an emission area and a non-emission area;
a via layer disposed on the substrate;
a (1-1)th electrode, a (1-2)th electrode, and a (1-3)th electrode disposed on the via layer in the emission area, the (1-1)th electrode, the (1-2)th electrode, and the (1-3)th electrode being spaced apart from each other;
a pixel defining layer disposed on the (1-1)th electrode, the (1-2)th electrode, the (1-3)th electrode, and the via layer, the pixel defining layer including an opening exposing a portion of each of the (1-1)th electrode, the (1-2)th electrode, and the (1-3)th electrode in the emission area:
an emission layer disposed on the pixel defining layer; and
a second electrode disposed on the emission layer, wherein
each of the (1-1)th electrode, the (1-2)th electrode, and the (1-3)th electrode includes a first layer disposed on the via layer and a second layer disposed between the first layer and the pixel defining layer,
the first layer includes a plurality of sub-insulating layers, each of the plurality of sub-insulating layers including a first sub-layer and a second sub-layer that are sequentially stacked, and
the first sub-layer and the second sub-layer have different refractive indices.

19. The display device of claim 18, wherein
the first layer includes a Bragg reflection layer to reflect light toward the second layer, the light that is emitted from the emission layer and transmitted toward the via layer, and
the first sub-layer includes a first inorganic layer having a first refractive index, and
the second sub-layer includes a second inorganic layer having a second refractive index.

20. The display device of claim 19, wherein
the first refractive index is smaller than the second refractive index,
the first inorganic layer includes SiOCF:H, and
the second inorganic layer includes Nb₂O₅.
